(19) United States
(12) Patent Application Publication
(10) Pub. No.: US 2019/0112181 A1
(43) Pub. Date: Apr. 18, 2019

(54) STABILE MICROMECHANICAL DEVICES

(71) Applicant: TEKNOLOGIAN TUTKIMUSKESKUS VTT OY, Espoo (FI)

(72) Inventors: Antti JAAKKOLA, Espoo (FI); Tuomas PENSALA, Espoo (FI); Mika PRUNNILA, Espoo (FI); Panu PEKKO, Espoo (FI); Jyrki KIIHAMÄKI, Espoo (FI); Aarne OJA, Espoo (FI)

(21) Appl. No.: 16/090,308

(22) PCT Filed: Mar. 31, 2017
(86) PCT No.: PCT/FI2017/050230

§ 371 Date: Oct. 1, 2018

(30) Foreign Application Priority Data
Apr. 1, 2016 (FI) 20165279

(51) Int. Cl. B81B 3/00; B81C 1/00

(52) U.S. Cl. CPC B81B 3/0078; B81C 1/00293; B81B 2201/0235; B81B 2201/0242; B81B 2203/0163; B81B 2201/0264; B81B 2203/0118; B81B 2203/0154; B81B 2201/0257

(57) ABSTRACT

The invention provides a micromechanical device comprising a support structure and a deflecting element connected to the support structure, wherein the deflecting element comprises at least one deformable member adapted to deform extensionally, flexurally or torsionally with respect to a deformation axis for allowing deflection of the deflecting element with respect to the support structure. Further, there are means for statically deflecting the deflecting element or detecting the magnitude of static deflection of the deflecting element. According to the invention, the deformable member is made of silicon doped with an n-type doping agent to a doping concentration of at least 1.1*10²⁰ cm⁻³. The invention allows for manufacturing micromechanical devices whose mechanical operation is not affected by prevailing temperature conditions.

### FIELD OF THE INVENTION

The invention relates to micromechanical devices. In particular, the invention relates to micromechanical devices comprising at least one mechanically statically deflecting (non-resonant) element and their functional stability in varying temperature conditions.

### BACKGROUND OF THE INVENTION

A wide range of micromechanical sensors are based on the measurement of a deflection of a mechanical spring element, caused by the physical measurand of interest. The deflection can be flexural deformation (bending), torsional deformation or extensional deformation. Examples of micromechanically implemented sensors include accelerometers, pressure sensors, microphones, gyroscopes, and voltage references. A standard material for micromechanical sensor devices is single crystal silicon.

A sensor can be subject to varying ambient temperature and it is often desired that the sensor's reading is minimally affected by the temperature. However, the elastic properties of silicon are, in general, temperature dependent: for example, the first order temperature coefficient of the elastic modulus of silicon, TCE₁, can be of the order of −60 ppm/° C., and this can be the limiting factor to the sensor's temperature stability. This level of temperature sensitivity can lead to over 6000 ppm (=0.6%) variation in the sensor output when the ambient temperature varies on a 125° C. temperature range, for example, from −40° C. to +85° C.

WO 2012/110708 discloses resonators or deflecting elements which have been doped so as to reduce their variation of performance as a function of temperature. The structures disclosed therein allow for the manufacture of resonators whose first order temperature coefficient is reduced.

Micromechanical silicon sensors used today often employ an active temperature compensation scheme to make the sensor output insensitive to the temperature: included with the sensor is a temperature sensing element, and calibration data is used to cancel the effect from the ambient temperature. However, avoiding an active temperature compensation scheme would be attractive since it could reduce the complexity, size, power consumption and production cost of the sensor as well as contribute beneficially to other performance parameters. In addition to micromechanical sensors, there are similar needs for other devices, which contain micromechanically moveable parts.

Thus, there is a need for improved micromechanical devices.

### SUMMARY OF THE INVENTION

It is an aim of the invention to provide a novel micromechanical device having high temperature stability. A particular aim is to provide a simpler, passively temperature compensated device.

The invention is based on manufacturing, on an n-doped silicon wafer, a deflecting element having a deformable member which is capable of deforming extensionally, torsionally or flexurally. It has been found that there exists a doping level of 1.1*10²⁰ cm⁻³ above which these particular deformation behaviors can be made essentially independent of temperature variations. In other words, the first and second order temperature coefficients of elasticity of the deflecting element can be made simultaneously very small or even zeroed, whereby the movement of the deflecting element is similar irrespective of its temperature.

Thus, the invention provides a micromechanical device comprising a support structure and a deflecting element connected to the support structure, wherein the deflecting element comprises at least one deformable member adapted to deform extensionally, flexurally or torsionally with respect to a deformation axis for allowing deflection of the deflecting element with respect to the support structure. Further, there are provided means for statically deflecting the deflecting element or detecting the magnitude of static deflection of the deflecting element. According to the invention the deformable member is doped with an n-type doping agent to a doping concentration of at least 1.1*10²⁰ cm⁻³.

Various embodiments are described that have as a common feature that that the extensional, flexural or torsional deformation of the deformable member is adapted to be affected by anisotropic elastic properties of the silicon material when the deflecting element is deflected with respect to the support structure. In particular, the shape and orientation of the deformable member with respect to its crystal structure are chosen, in combination with the selected doping concentration, so that the deformation is affected by anisotropy in a way reducing the first and second order temperature coefficients of elasticity of the deformable member, in particular simultaneously zeroing the first and second order temperature coefficients of elasticity of the deformable member and therefore the whole deflecting element.

Minimizing or even zeroing the coefficients of elasticity can be achieved above the abovementioned doping concentration by providing the deformable member at a certain angle range with respect to the crystal lattice of the deformable member, typically in the plane of the wafer. The wafer is typically a (100) or (110) oriented silicon wafer. The optimal angle depends on the particular geometry and type of deformation concerned. For the extensional, flexural and torsional deformations, the angle is determined with respect to the [100] or [110] crystal direction. Several examples for all these deformations and various practical applications are given later in this document.

According to one aspect, the deformation is adapted to be extensional or flexural and the deformation axis of the deformable member is oriented at an angle of 20±20 degrees with respect to the [100] crystal direction of the wafer. According to one embodiment, applicable for a beam-type deformable member, whose deformation takes place in the transverse or longitudinal direction of the beam, the deformation axis is oriented at an angle of 20±15, in particular 17±10 degrees with respect to the [100] crystal direction of the wafer. That is, there is a significant angle deviation between the deformation axis of the beam and the [100] crystal direction of the lattice. According to another embodiment, the deformable member is a plate suspended from its lateral edges as a flexural membrane, whereby the deformation axis can be also smaller, even 0 degrees if the plate is non-square. This aspect allows for passive zeroing of first and also higher order temperature coefficients of flexural and extensional movements, whichever is applicable for the particular device, of the deformable member with respect to the deformation axis. This aspect can be used for the manufacture of temperature compensated pressure sensors, acceleration sensors or voltage reference devices, to mention some examples.

According to another aspect, the deformation is adapted to be torsional and the deformation axis of the deformable member is oriented at an angle of 0±35 degrees with respect to the [110] crystal direction of the wafer. This allows for passive zeroing of the first and optionally also higher order temperature coefficients of the torsional movement around that axis. The angle can be for example ±5 . . . 30 degrees, i.e. moderately tilted with respect to the [110] direction. This aspect can be used for example for the manufacture of gyroscopic sensors or accelerometers.

More specifically, the invention is characterized by what is stated in the independent claim.

The invention offers considerable advantages. First, the invention allows for manufacturing of non-resonant devices that operate in a stable way irrespective of prevailing temperature. Second, the temperature compensation can be completely passive, whereby power consumption of the devices is minimized. Both these factors are significant for example in sensor applications, as the sensor technology develops and other sources of errors are also reduced and sensors are incorporated into smaller and smaller apparatuses, such as handheld or wearable devices.

Of particular importance is that by orienting the deflecting member or members correctly, both TCE₁ and TCE₂ can be made simultaneously close to zero, and the overall variation of elastic properties of the device as a function of temperature can be made very small. This is called as second order temperature compensation. By means of the invention, on a temperature range of T=−40 . . . +85 C the variation of the elastic modulus E can be for example less than +/−20 ppm (parts per million).

Selected embodiments of the invention are the subject of the dependent claims.

In some embodiments, the deformable member of the deflecting element comprises a beam whose deformation axis is oriented along the longitudinal axis or a transverse axis of the beam. There may also be a plurality of deformable members, such as a plurality of such beams connected to each other, for example in a meandering formation or in ring formation.

In some embodiments, the deformable member comprises a plate having at least one axis of symmetry and the deformation axis is oriented along the axis of symmetry. According to one embodiment, the plate is manufactured from a (100) oriented silicon wafer spanned to the support structure as a flexurally deformable membrane, whereby the dimensions of the plate and angle with respect to the [100] crystal direction of the wafer are chosen to provide a lower first order temperature coefficient of elasticity for the plate than that of square plate with main axes parallel to the [100] crystal direction of the wafer. For example, the plate can have an aspect ratio different from 1:1.

In some embodiments, the doping concentration, shape and orientation of the deflecting member are chosen so as to provide the first order temperature coefficient of elasticity of the deflecting member below 1 ppm/C. Further, the doping concentration, shape and orientation of the deflecting member can be chosen so as to provide the second order temperature coefficient of elasticity of the deflecting member below 12 ppb/C².

In some embodiments, the deflecting element comprises, in addition to the at least one deformable member, at least one a non-deformable member, which is adapted to move due to the deformation of the at least one deformable member. This embodiment can be utilized e.g. in pressure sensors and acceleration sensors.

According to some embodiments, the device is a sensor device comprising means for detecting the magnitude of static deflection of the deflecting element. For example, in pressure sensor or acoustic sensor, the deflecting element may forms a diaphragm adapted to deflect through flexural deformation of the at least one deformable member forming at least part of the diaphragm due to external pressure affecting the deflecting element. As another example, the device can be an accelerometer, wherein the deflecting element comprises a mass element suspended to the supporting structure by the at least one deformable member, whereby the at least one deformable member is adapted to deform, preferably flexurally or torsionally, due to acceleration experienced by the device. As a still further example, the device can be a gyroscopic sensor, wherein the deformable member is arranged as a Coriolis force-deformable member thereof. The device can also be a micromechanical drive comprising means for statically deflecting the deflecting element. Finally, the device can be a voltage reference device comprising means for exerting an electrostatic force on the deflecting element for deforming the deformable member by means of a voltage.

In some embodiments, the n-type doping concentration in the at least one deformable member can be at least 1.2*10²⁰ cm⁻³. The doping agent can be phosphorus, antimony or arsenic, for example.

Next, selected embodiments of the invention and advantages thereof are discussed in more detail with reference to the attached drawings.

### BRIEF DESCRIPTION OF THE DRAWINGS

FIGS. 1A and 1B illustrate in an in-plane view and perspective view, respectively, of a beam oriented at an angle with respect to the [100] crystal direction.

FIG. 1C illustrates an in-plane view of a plate with sides oriented at an angle with respect to the [100] crystal direction.

FIGS. 2A and 2B show a cross-sectional side views of a pressure sensor or acoustic sensor according to one embodiment of the invention in a “zero pressure state” and “high pressure state”, respectively.

FIGS. 2C-2G show schematic top views of a pressure sensor or acoustic sensor according to various embodiments of the invention.

FIG. 2H shows a cross-sectional side view of a structure alternative to that illustrated in FIGS. 2A and 2B.

FIGS. 2I-2M show schematic top views of a pressure sensor or acoustic sensor according to further embodiments of the invention

FIGS. 2N-2S show a schematic cross-sectional view and top views of a pressure sensor or acoustic sensor according to still further embodiments of the invention

FIG. 3A illustrates a cross-sectional side view of a spring-and-mass type sensor, such as an acceleration sensor, according to one embodiment of the invention.

FIGS. 3B and 3C illustrate an acceleration sensor according to one embodiment of the invention in a steady state and state where acceleration is applied, respectively.

FIG. 3D shows an example of a two-dimensional acceleration sensor which can take advantage of the present invention.

FIG. 4 shows a torsional deflecting element according to one embodiment of the invention.

FIG. 5 depicts a cross-sectional side view of a voltage reference device according to one embodiment of the invention.

FIGS. 6A-6C show simulated graphs to illustrate the parameters zeroing temperature coefficients TCE₁ and TCE₂ of an extensional/flexural spring element, optionally with temperature expansion taken into account.

FIGS. 7A-7D show simulated graphs illustrating how the out-of-plane aspect ratio, doping concentration and angle with respect to crystal of a torsional spring element affect its temperature stability.

### DETAILED DESCRIPTION OF EMBODIMENTS

### Definitions

The term “deflecting element” refers to a statically moveable element of a micromechanical device.

“Static” herein means non-resonant behavior. For example, static movement/deflection of or static force exerted on an element or portion thereof means non-resonant movement/deflection of or force exerted on the element, that does not bring the element or portion thereof to mechanically resonate. Correspondingly, a statically moveable element is an element, whose function in the device concerned is not based on bringing the element into mechanical resonance for example by excitation of acoustic waves into the element. Instead of that, the function is based on statically deflecting the deflecting element and/or detecting the magnitude of deflection of the deflecting element. It should be noted that “static” does not exclude dynamic or even oscillatory but non-resonant behavior, in particular such taking place at an irregular cycle or at a regular frequency which is different from any acoustic resonance frequency of the part concerned. For example, the present device can be adapted to sense or produce acoustic waves or to drive or sense micromechanical movement at non-resonant frequencies.

The term “deformable member” means a portion of the deflecting element, which is adapted to experience a flexural, extensional or torsional change of shape (deformation) when the device is used, and therefore enabling the movement of the deflecting element. A deflecting element may contain one or more deformable members. The deflecting element may consist of the deformable member or contain also additional members, such as non-deformable members or members, which are adapted to deform but are not temperature-compensated in accordance with the present invention.

“Deformation axis” refers to the linear direction, with respect to which the deformation takes place. In the case of extensional deformation, the deformation axis is parallel to the dimension of the deformable member, which is changed due to the extension (including shortening). In the case of a beam, the extensional axis preferably lies along longitudinal main axis of the deformable member (length-extensional deformation). In the case of flexural deformation, the deformation axis is in the plane of the flexural movement and parallel to the dimension of the deformable member at the state, from which the deformable bends. In the case of a beam, the deformation axis is typically parallel to the transverse or longitudinal main axis of the beam. In the case of torsional deformation, the deformation axis is the axis around which the torsional movement takes place. In the case of a beam, this typically corresponds to the longitudinal main axis of the beam. It should be noted that such designs, where two or more these types of deformations take place simultaneously, are not excluded.

Flexural movement can take place either in the lateral plane of the device (in-plane mode), out of that plane (out-of-plane mode) or both.

The terms “lateral” and “in-plane” herein mean directions in the plane co-planar with the wafer the device is manufactured to. “Out-of-plane” is a direction perpendicular to that plane.

The term “beam” refers to a deformable member whose in-plane aspect ratio (length to width) is at least 2:1. Typically, the in-plane aspect ratio is at least 5:1. The aspect ratio can be for example 10:1 or more. The term out-of-plane aspect ratio refers to the ratio of height (out-of-plane dimension) to width of the beam. The out-of-plane aspect ratio is not critical for length-extensional or flexural beams, whereas for torsional modes, the out-of-plane aspect ratio is typically 2:1 . . . 1:2, in particular 1.5:1 . . . 1:1.5, such as 1:1.

“Main axis” of an element means an axis of elongation and/or symmetry of an element. For example main axes of a rectangle or square are oriented in the directions of the sides of the rectangle or square and coincide with its symmetry axis. The longitudinal axis of a beam is its main axis directed along the elongated direction (length direction) of the beam.

“Suspending” of a deflecting element means arranging the element in such a way that at least part of it is able to move with respect to the support structure in the desired way. Typically, the temperature-compensated deformable member or members in accordance with the present invention form(s) the suspension, although there may also be other types of zones providing suspension present.

Crystal directions are denoted with the bracket notation, e.g. [100]. By this notation any equivalent direction is meant: e.g. [100] is equivalent to [010] or [001].

The term “zeroing” of a first and/or second order temperature coefficient refers in particular to reduction of the temperature coefficient of elasticity TCE₁ and/or TCE₂, respectively, of the given material below a predefined level of 1 ppm/C or 12 ppb/C², respectively, unless stricter limits are given. Unless otherwise indicated or clear from the context, the TCE₁ and TCE₂ values given and terms like “decrease”, “reduce” and “increase” of TCE₁ or TCE₂ refer to their absolute values, i.e. deviation from zero. It should however be noted that both TCE₁ and TCE₂ can take a negative value (undercompensation) or positive value (overcompensation).

The notation X±Y means any value between and including X−Y and X+Y. The notation ±X . . . Y means any value between and including −X and −Y or X and Y.

The silicon material herein discussed is preferably silicon.

The term doping concentration or doping level refers to the concentration of the active charge carriers. This concentration is typically a fraction of the concentration of the dopant atoms, such as phosphorus, that introduce the charge carriers to the silicon crystal lattice.

Deformable Member and Sensing or Driving the Deflection

As briefly explained above, the present micromechanical device comprises a support structure and a deflecting element connected to the support structure. The deflecting element comprises at least one deformable member adapted to deform extensionally, flexurally or torsionally, generally acting as a spring in the device. The motion of the deflecting element is passively temperature compensated. For achieving this, the deflecting element is manufactured from n-doped silicon. Typically, the whole functional layer of the device is manufactured from a (100) or (110) oriented silicon wafer, wherein at least the deformable member is doped with an n-type doping agent. The doping is preferably homogeneous. The shape and angle of the deformable member are chosen so that the deflection benefits from the anisotropic properties of silicon so as to reduce the effect of temperature.

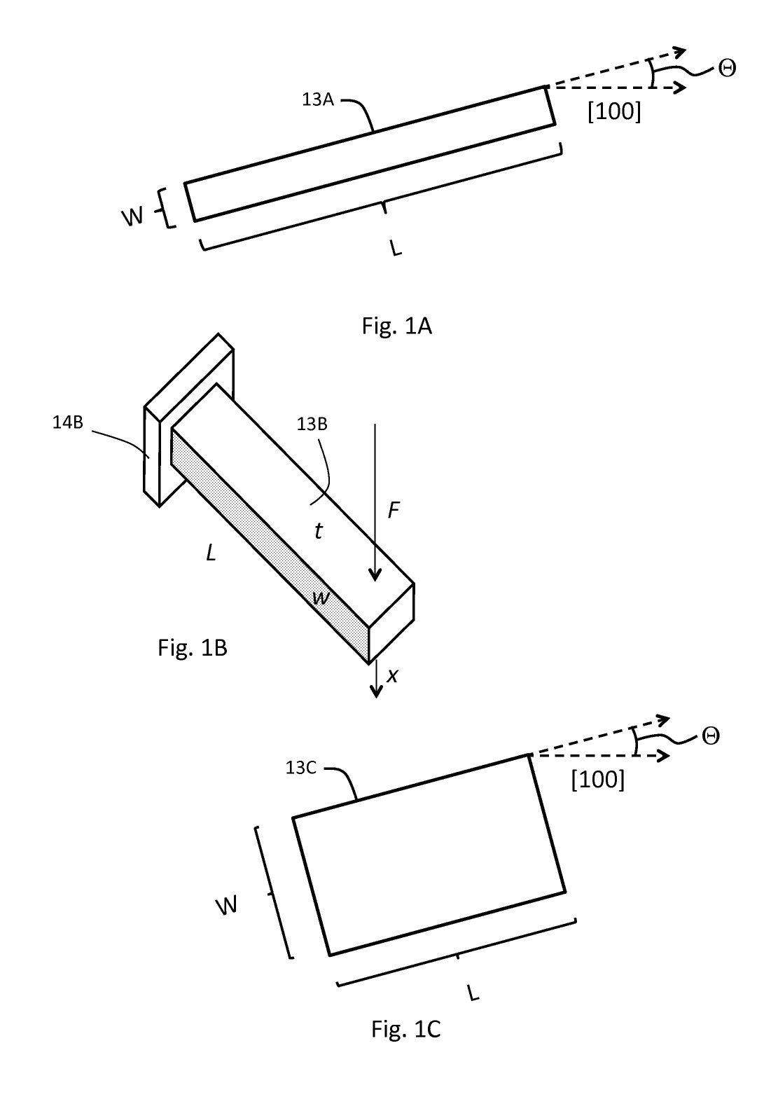

FIG. 1A shows, as an example of a deformable member, a rectangular beam 13A having a length L and width W. The longitudinal axis of the beam is oriented at an angle θ with respect to its [100] crystal direction. In general, the beam can deform extensionally in any direction (in typical applications in the longitudinal direction), flexurally in in-plane or out-of-plane direction, or torsionally around its longitudinal axis, depending on its attachment to its supporting structure (not shown).

To exemplify flexural deformation, in more detail, FIG. 1B shows a beam 13B extending from one end thereof from a stationary support structure 14B, thereby forming a spring element. If a force F is applied on the beam 13B, herein in an in-plane direction transverse to the longitudinal direction of the beam 13B, the beam experiences a bending (or flexural) deformation, and the free end of the beam moves by x=F/k, where k is the spring constant. The spring constant k is proportional to the elastic modulus E, thickness t, width w and length L as follows:

k˜(Etw³)/L³.

The temperature coefficient of the spring constant, TC(k), relates to temperature constants of the elastic modulus (TCE) and thermal expansion (TCL), respectively, as

TC(k)=TCE+TCL (Eq. A).

For an extensional deformation (when force F is directed along the length dimension of the beam), the spring constant would be

k˜Etw/L,

and the temperature coefficient TC(k) is similar as in Eq. A

That is, in general, the mechanical behavior of the spring depends on prevailing temperature, which is not desired in applications requiring mechanical accuracy. Similar considerations apply to other forms of elements and other types of deformations. However, by arranging the deformation axis at a suitable angle with respect to the crystal in accordance with the present disclosure, the effect of temperature can be diminished or even avoided in practice.

FIG. 1C exemplifies a rectangular plate 13C whose main axes are oriented at an angle θ with respect to its [100] crystal direction. Such plate can also experience flexure in particular in the out-of-place direction, torsion or extension whose corresponding temperature coefficients can be minimized by adjusting the angle θ.

In an embodiment applicable to flexural and extensional deformations, the flexural or extensional axis of the deformable member is oriented at an angle (θ) of 17±10 degrees with respect to its [100] crystal direction. The angle can be for example 17±8 degrees.

In an embodiment applicable to torsional deformation, the torsional axis of the deformable member is oriented at an angle of 0±30 degrees with respect to its [110] crystal direction. The angle can deviate e.g. 5 . . . 30, in particular 5 . . . 20 degrees from the [110] direction.

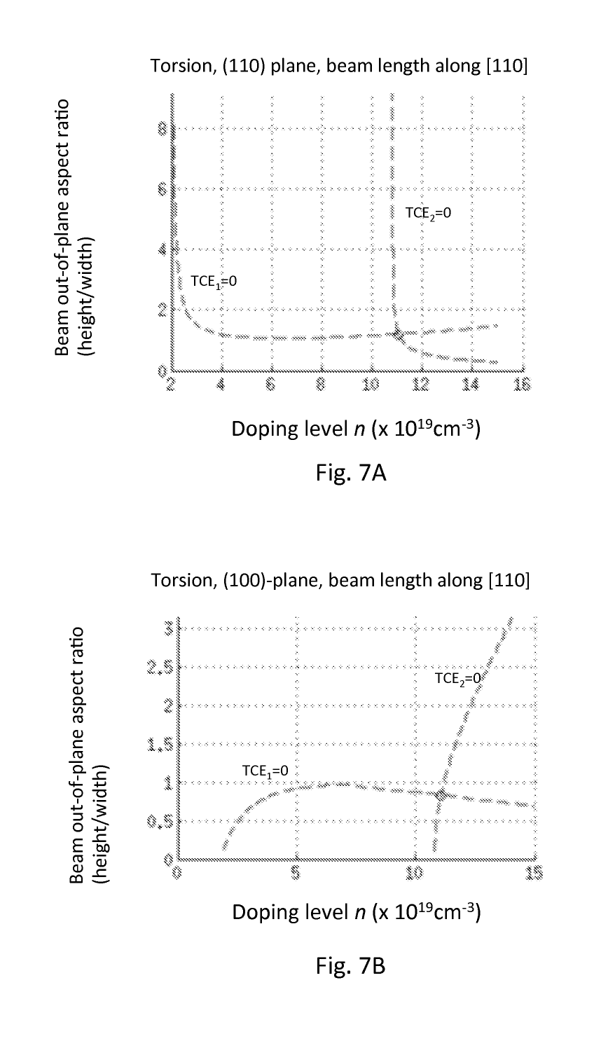

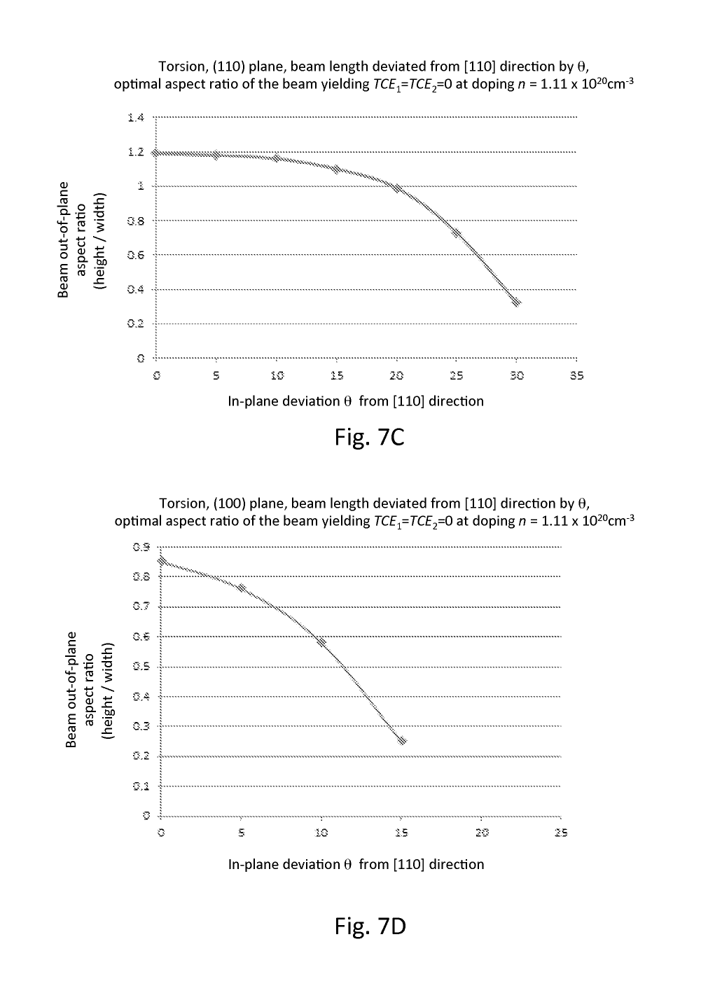

In an embodiment applicable to torsional deformations, the out-of-plane aspect ratio of the deformable member is chosen to minimize both first and second order temperature coefficients for a given angle. The aspect ratio can be for example less than 2, and in particular less than 1.5. In particular, for a torsional potion in the (110) plane, the out-of-place aspect ratio can be less than 1.3, such as 0.1 . . . 1.2 and for a torsional member in the (100) plane, the out-of-plane aspect ratio can be less than 1, such as 0.1 . . . 0.9. In the latter case, the angle range within which both zero first and second order temperature coefficients can be found is somewhat smaller, i.e., 0±20. FIGS. 7A-7D represent graphs, which provide support for the ranges herein defined.

It should be noted that although only rectangular beams and plates are exemplified herein in detail, the deformable member may take more complex shapes and in particular may comprise a plurality of beams or plates connected with each other. Some examples of structures utilizing interconnected beams (deformable closed loop springs and meander springs) are given below.

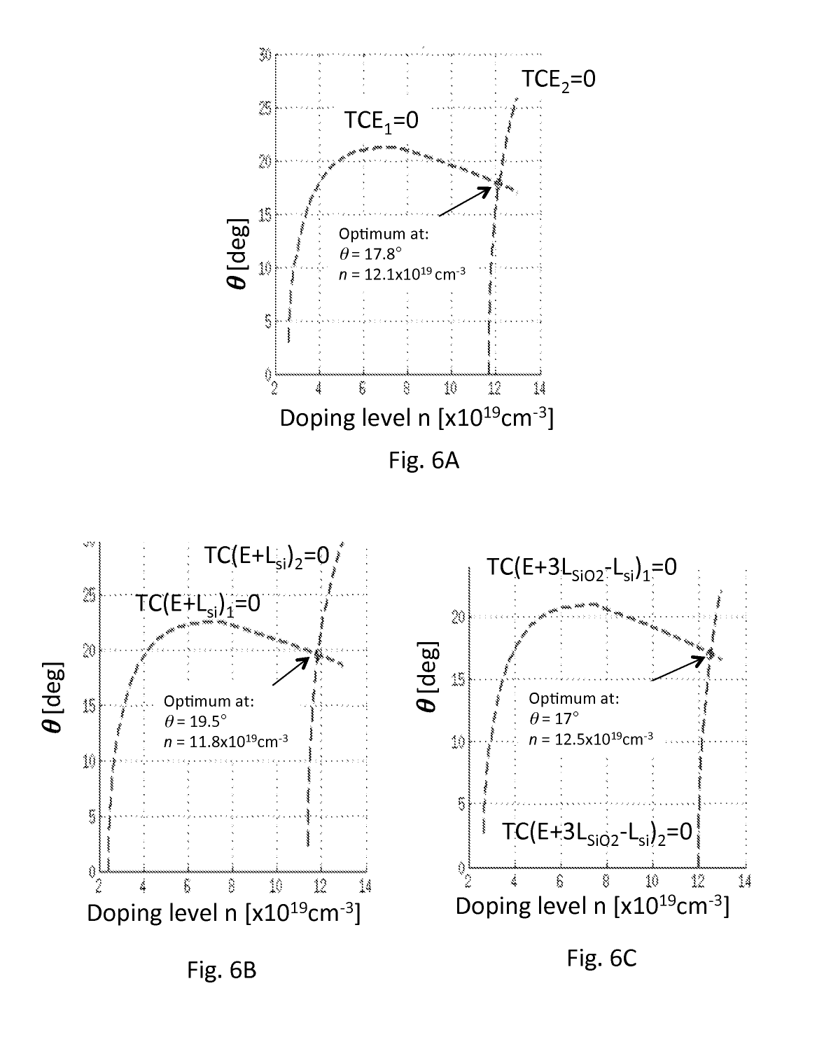

It should also be noted that the deflecting element, and also the deformable member thereof, can consist of single crystalline silicon only, but it is also possible that it consists of multiple materials. For example, it can be that on top of a silicon spring is a layer of piezoelectric material, such as aluminium nitride, and a layer or multiple layers of metals, such as aluminium or molybdenum, providing electrodes to the piezoelectrode material. Typically the proportional mass of the other materials is less than 20% that of silicon. Importantly, the other materials typically have negative first- and second order temperature coefficients of their elastic modulus, and they decrease the values of the first- and second order temperature coefficients of the elastic modulus of the compound spring element. As a result, the optimal doping level is increased, and the optimal in-plane angle is decreased (For example, in FIG. 6A, the TCE₁=0 and TCE₂=0 curves move down and right due to other materials present).

The means for statically deflecting the deflecting element (driving) or detecting the magnitude of static deflection of the deflecting element (sensing) can be based on electrostatic (capacitive) interaction, piezoelectric interaction or magnetic interaction, to mention some alternatives. Sensing can occur for example by detecting the distance between at least one reference point, which is static with respect to the support structure, and at least one point of the deflecting element, which is adapted to move due to deformation of the deformable member. On the other hand, in drive applications, there may be provided internally in the device means for exerting a static force, such as an electrostatic force, on the deflecting element for deforming the deformable member.

Next, more detailed embodiments suitable for practical applications are discussed. It should be noted that although the structures and functions are described in the context of particular applications for clarity reasons, similar structures and design principles can be used in other applications requiring similar movement.

Pressure Sensor or Acoustic Sensor (Microphone)

The examples discussed herein represent structures suitable for a pressure sensor suitable for sensing either steady prevailing pressure (e.g. barometer) or dynamically changing pressure (e.g. external acoustic waves, such as sound waves in a microphone).

Conventional micromechanical pressure sensors are based on a thin diaphragm that is deflected due to a pressure difference. The displacement of the diaphragm is sensed capacitively, for example. The diaphragm is typically symmetric in its in-plane shape, for example a square, hexagon or a disk, and typically the thickness of the membrane is essentially homogeneous. However, to create a temperature compensated pressure sensor that is based on n-type doped silicon, conventional approaches do not work as they do not utilize the anisotropic mechanical properties of silicon. In the following, exemplary structures that can be used to achieve passive temperature compensation are described.

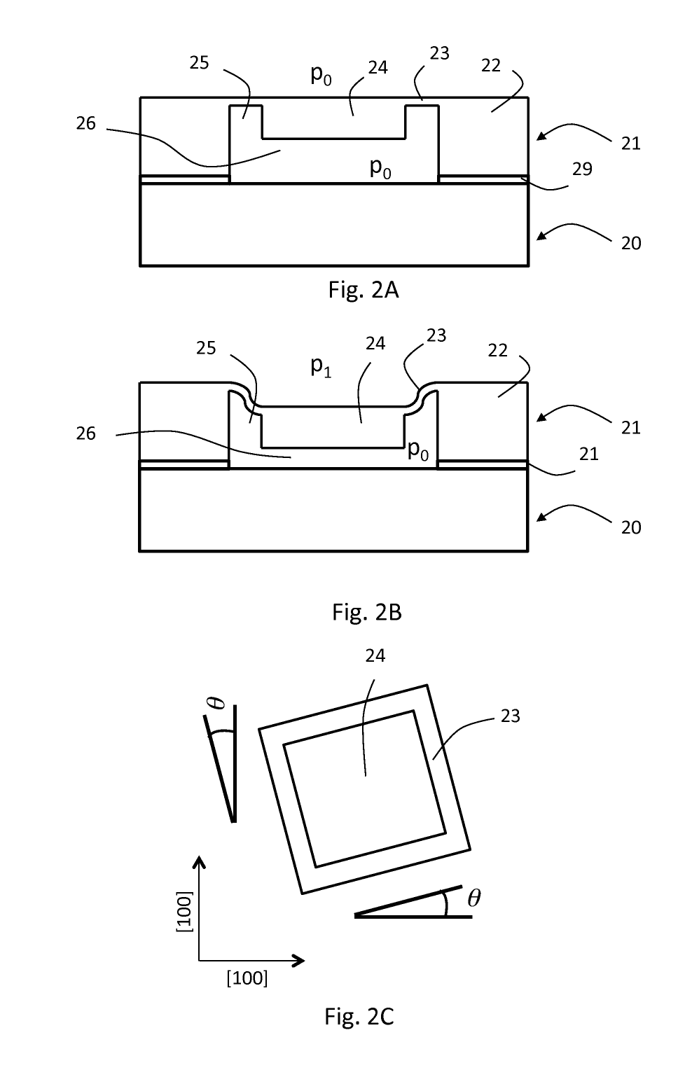

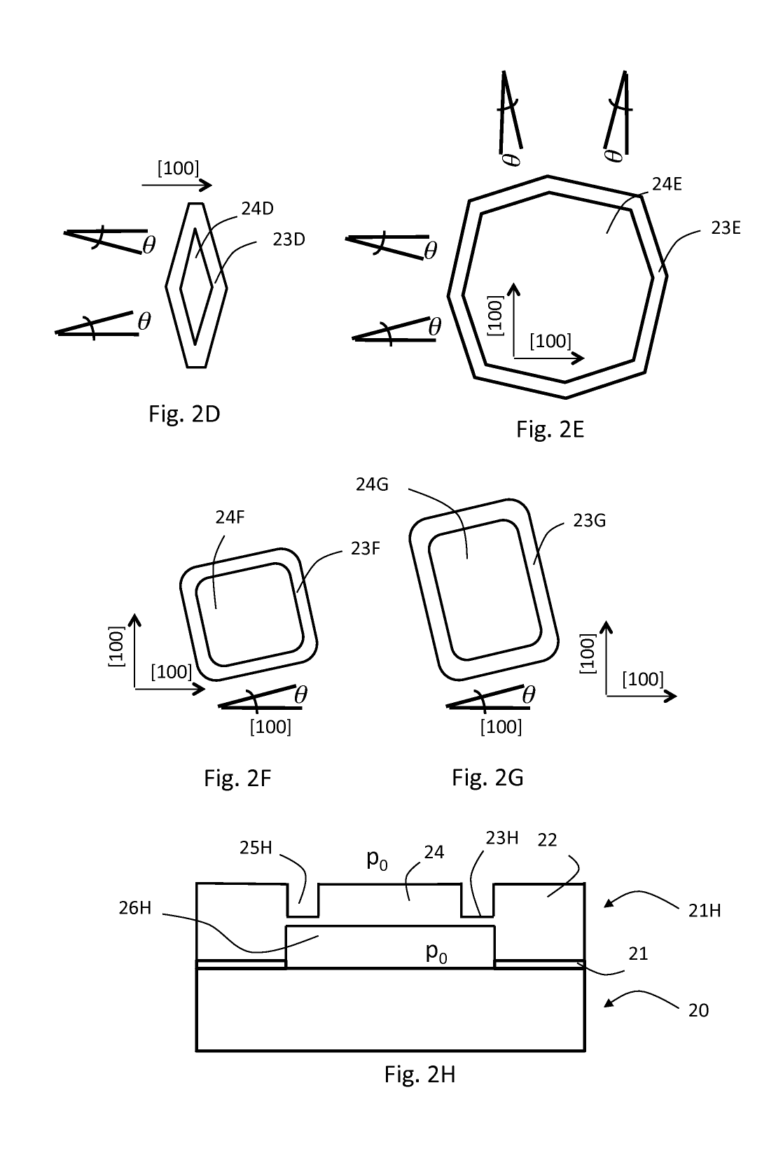

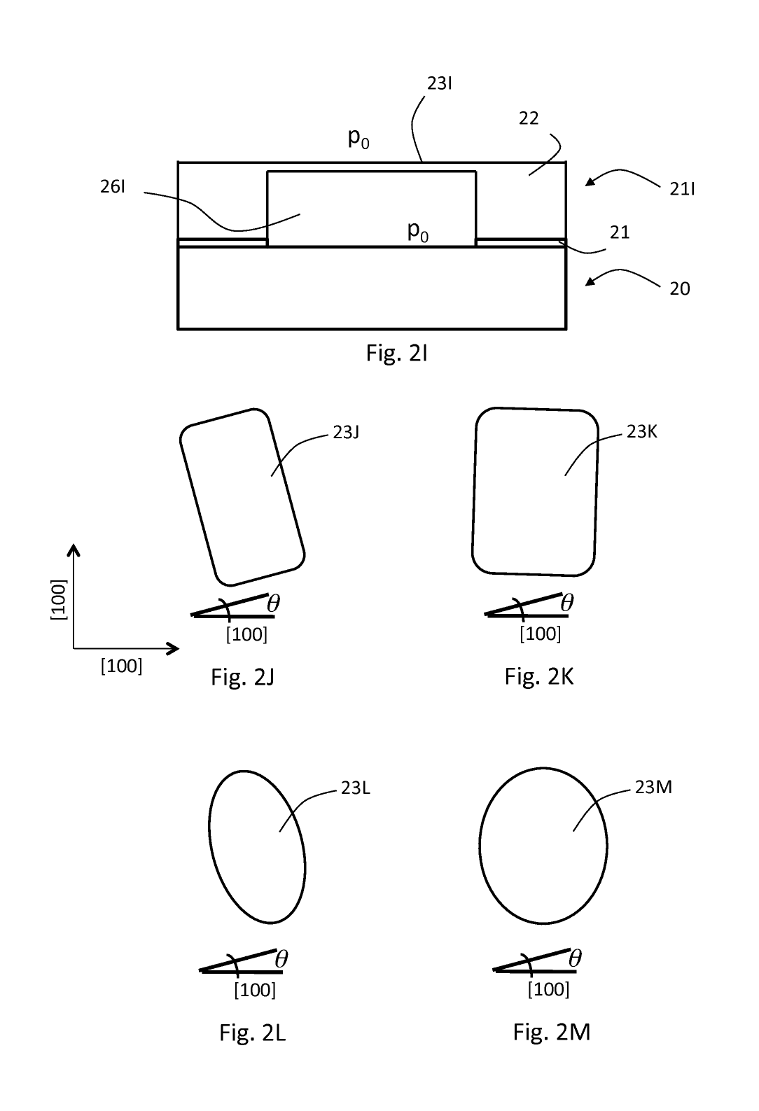

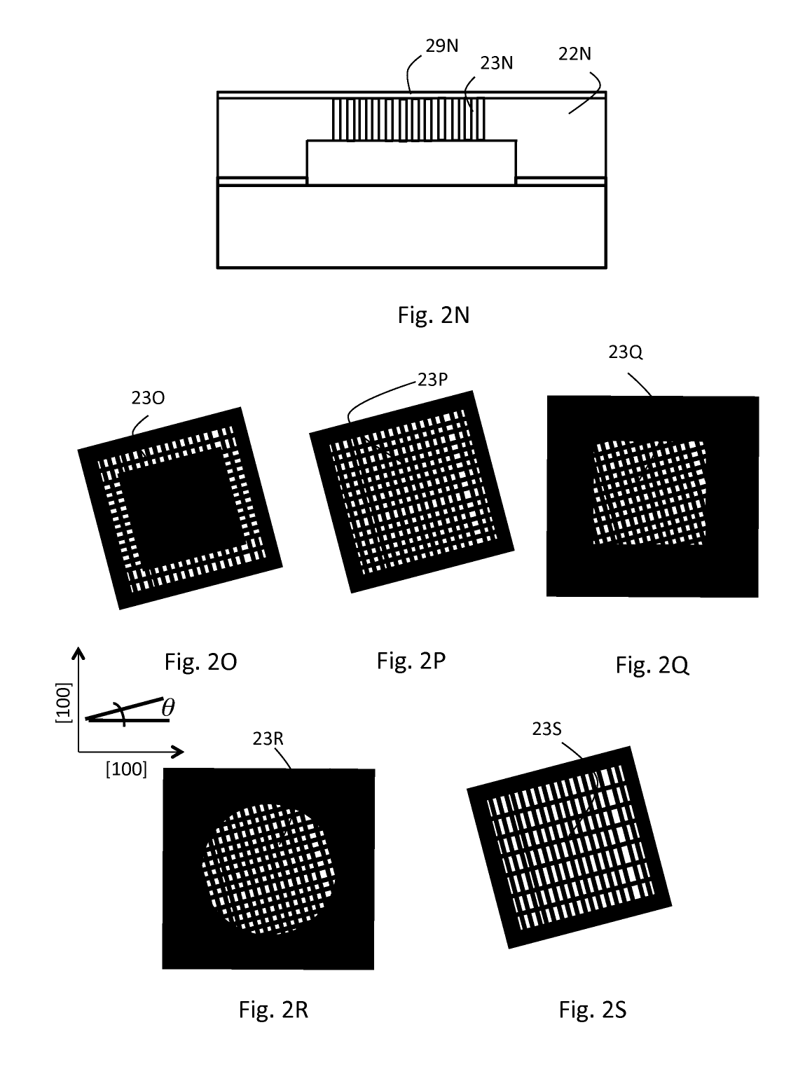

In the following, three basic forms of the diaphragm are described: A first one with a non-deformable central portion and wherein the deformable member is located between the central member and the support structure in ring formation, such as in the form of a plurality of interconnected beams, having a thickness smaller than the central member (FIGS. 2A-2H). A second one with a flexural membrane forming the deformable member, the membrane having an aspect ratio different from 1:1, such as 2:1 or more, in particular 3:1 or more (FIGS. 2I-2M). A third one with a mesh of beams forming the deformable members, and wherein at least some of the beams are arranged at a non-zero angle with respect to the [100] crystal direction of the silicon material (FIGS. 2N-2S). These exemplary forms of diaphragms can also be combined to form functional variations.

In general, in the embodiments according to FIGS. 2A-2H and FIGS. 2N-2S essentially the deformation of the diaphragm is constrained by geometry such that at each location (except for potential corners, for example), the deformation occurs in a plane that is at the optimized angle θ with respect to the [100] crystal direction. This allows for benefiting from the anisotropic properties of silicon. On the other hand, FIGS. 2I-2M represent a special case, where the membrane is deformable simultaneously more freely in all directions, but the aspect ratio of the deformable member is chosen so that the deformation as a whole is affected by the anisotropic properties of silicon. In the latter case, the angle θ of the member as whole with respect to the [100] direction of the crystal can also be zero.

In an example represented by FIGS. 2A and 2B, there is provided a substrate layer 20 and a functional layer 21 made of silicon material provided on the substrate, preferably separated by a separating layer 29. The functional layer is shaped to comprise a rigid frame 22 and a deflecting diaphragm 23, 24, which together with the substrate 20, define a closed reference pressure cavity 26. The diaphragm 23, 24 comprises a non-deformable central member 24 and deformable outer members 23 forming a deformable loop-like portion around the central member. The deformable members 23 have been formed by providing a trench 25 inside the cavity such that the thickness of the material is reduced at respective locations.

The reference pressure inside the pressure cavity 26 is p₀. If the external pressure is also p₀, the diaphragm is in a first position. Herein the deformable members 23 are in a non-deformed state. If the external pressure rises to a value p₁, the pressure difference affecting over the diaphragm 23, 24 causes the deformable members 23 to deform flexurally and the central member 24 is pushed towards the substrate 20. The magnitude of deflection of the diaphragm can be measured using suitable means (not shown), whereby the magnitude of the pressure difference can be determined. The measurement of the deflection can be based for example on measuring the capacitance between the central member and substrate using suitable electrodes provided to them.

FIG. 2C shows an exemplary top view of the structure of FIGS. 2A and 2B. Four deformable members 23 are arranged in square geometry to entirely surround the central member 24 so as to form the diaphragm 23, 24. The main axes of the whole structure are arranged at an angle θ with respect to the [100] crystal direction of the functional layer 21. The deformable members 23 can be thought to be beams which are connected to each other at their ends and each of which is tilted by angle θ from the [100] crystal direction. This way, when pressure p₁ is applied, at each particular location (potentially apart from minor zones at the corners), the deformable members 23 experience flexure with respect to an axis that is aligned at angle θ. Consequently, the overall temperature coefficient of motion is reduced and a more temperature-stable sensor is achieved.

The central member being non-deformable and therefore moving in a piston-like manner within the frame “forces” the flexure of the deformable members to take place essentially in a plane that is aligned at an angle θ with respect to the [100] crystal direction, whereby passive temperature compensation is achieved.

FIGS. 2D-2G illustrate alternative diaphragm geometries. In the geometry of FIG. 2D, there are provided four interconnected beams 23D defining the deformable portion, and a central member 24D, together forming the diaphragm. Differing from the setup of FIG. 2C, the beams 23D are not arranged in perpendicular configuration, but as a parallelogram, each of the beams however having a main axis (herein transverse axis) aligned at an angle θ with respect to the [100] crystal direction. This embodiment has particular significance if manufactured on a wafer with normal in the [110] crystal direction.

FIG. 2E shows an alternative diaphragm geometry with eight interconnected beams 23E, each of which (both longitudinal and transverse axes) are arranged at an angle θ with respect to the [100] crystal direction. The geometry approaches circular geometry, however efficiently benefiting from passive temperature-compensation. As the angle between neighboring beams is wider than in the configuration of FIG. 2C, potentially disadvantageous effects caused by the “corners” may be reduced.

FIGS. 2F and 2G show variations of the previous structures, with rounded corners and rectangular overall shape, respectively.

Instead of thinking the described loop structures as being formed of interconnected beams, they can be more generally considered as loop-shaped plates with sections arranged at distinct angles with respect to the crystal.

It should be noted that the angle θ can be chosen so as to overcompensate the temperature coefficients of the beams, whereby the effect of corners, for example, which may affect the overall flexural behavior of the diaphragm, can be compensated away.

FIG. 2H shows an alternative cross-sectional structure for a pressure sensor. It differs from that of FIG. 2A in that the trench is arranged on the outer side of the functional layer 21H. Thus, the deformable members 23H are formed between the frame 22 and the central member 24 closer to the substrate and the reference pressure cavity 26H has a slightly different shape. Functionally, this structure operates in the same way as that of FIG. 2A.

FIGS. 2I and 2J-2M show variations, where the whole diaphragm is deformable, like a membrane, therefore resembling a conventional micromechanical pressure sensor. Thus, in the functional layer 21I, the deformable member 23I (23J-M) covers the whole space formed by the frame 22 so that a reference pressure cavity 26I is formed. In the embodiment of FIG. 2J, the main axes of the structure deviate by angle θ from the [100] crystal direction. In this embodiment, the whole diaphragm can experience flexure, significant portion of which takes place with respect to a flexural axis that is in angle θ or close to it. Therefore, the overall motion is temperature compensated. In the embodiment of FIG. 2K, which represents a special case, the main axes are aligned with the [100] crystal direction, but the aspect ratio of the plate is accurately designed to provide flexural anisotropy that minimizes the temperature coefficient of elasticity of the flexural deformation. The aspect ratio can be e.g. 2:1 or more, in particular 3:1 or more. The embodiments of FIGS. 2L and 2M correspond to those of FIGS. 2J and 2K, correspondingly, but with elliptic plates instead of rectangular.

FIGS. 2I-2M illustrate that temperature compensated behaviour can be achieved by re-shaping an initially symmetric square or disk in-plane geometry (of aspect ratio 1:1) of an essentially homogeneously thick membrane to one with elongated in-plane shape and thus higher in-plane aspect ratio. In general, at least aspect ratio of 3:1 is needed to achieve temperature compensated behaviour. With higher aspect ratios than 3:1 the in-plane angle theta can be varied for example in the range of 0 . . . 20, in particular 0 . . . 15 degrees to achieve temperature compensated behaviour.

FIGS. 2N and 2O-2S illustrate embodiments, where there the diaphragm is fabricated as a compound element, comprising a base member 23N, made for example of single crystal silicon and a thin membrane 29N (or multiple thin membranes) superimposed thereon. These two parts are both deformed due to external pressure. The base member 23N extends from the support structure 22N and provides the mechanical stiffness and the thin membrane 29N, which can be silicon nitride, for example, provides an air-tight interface withstanding the pressure difference on the two sides of the membrane 29N but minimally contributing to the mechanical stiffness of the diaphragm as a whole. The base member 23N is through-patterned in such a way that a grid on beam-like elements is formed, each beam experiencing flexural and/or extensional deformation, thus benefiting from the temperature compensated behaviour when the doping level and orientation of the beams are suitably selected. Thus, there is a plurality of beams acting as deformable members in the present context. This kind of a structure is called a beam mesh herein.

FIG. 2O illustrates an exemplary top view of the structure of 2N. There, the beam mesh 23O is provided in a ring formation on the fringe portion of the diaphragm such that the individual beams, and herein also the whole diaphragm, are arranged at an angle θ with respect to the [100] crystal direction. The central portion is preferably non-deformable, like in the embodiments of 2A-C. FIG. 2P shows an alternative embodiment, where the beam mesh covers the whole diaphragm. FIG. 2Q shows a variation where the diaphragm itself, herein a rectangular/square one, is aligned with the [100] crystal direction but individual beams of the beam mesh 23Q are at an angle θ with respect to the [100] crystal direction. FIG. 2R shows an embodiment, where the diaphragm is circular but the beams are at the tilted angle with respect to the crystal and therefore provide the desired functionality. FIG. 2S shows a variation of FIG. 2P with a non-square beam mesh.

FIGS. 2N and 2O-2S represent an example where there may be other material than single crystal doped silicon present (if the membrane is not silicon) and affecting the mechanical properties of the device. This can be taken into account by “overdoping” the silicon to a concentration of at least 1.2*10²⁰ cm⁻³, for example, or adjusting the tilt angle suitably, e.g. within the range of 17±10 degrees.

Similar structures, optionally with open cavity instead of a closed reference pressure cavity, can be used as a mass sensor for physical samples, to mention only one additional sensor application.

By providing means for statically moving the membrane (instead or in addition to means for sensing its position), a similar structure can be used as an acoustic wave-producing element (speaker) or as a drive for precise micromechanical piston-like movements.

Acceleration Sensor

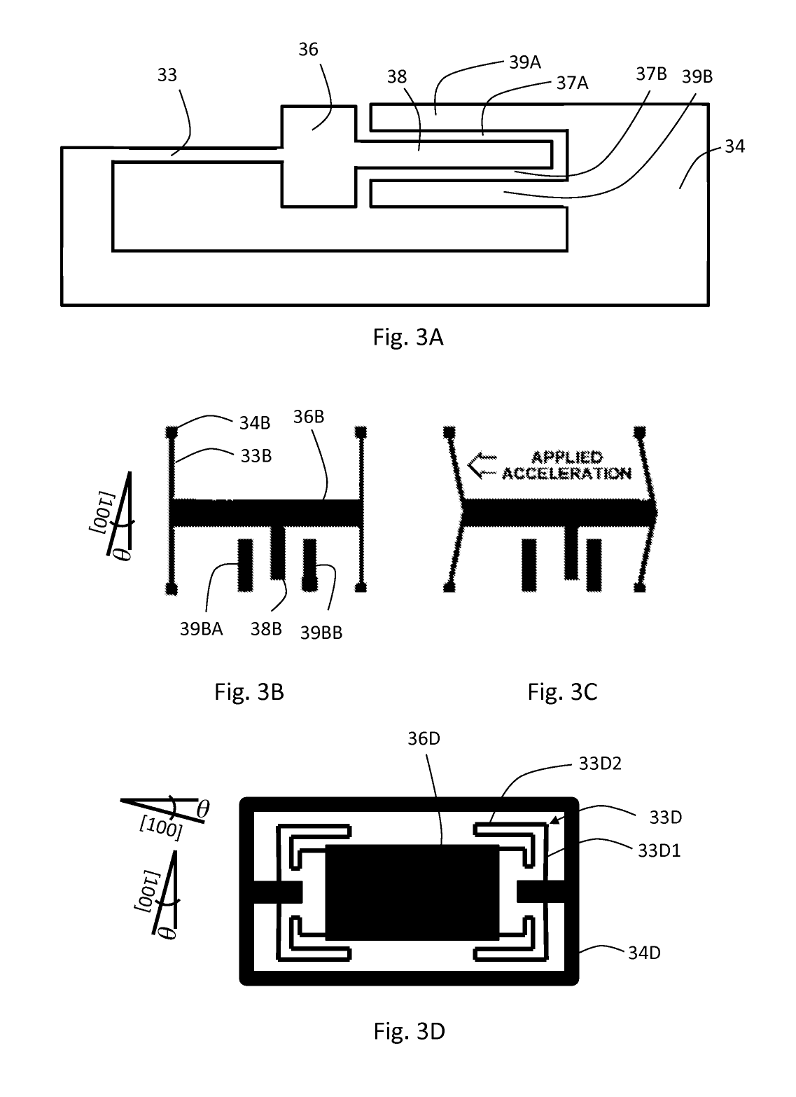

FIG. 3A shows an exemplary structure suitable for an accelerometer. It comprises a support structure 34 comprising steady protrusions 39A and 39B arranged at a distance from each other. Extending also from the support structure 34 is a deflecting element comprising a deformable member 33, in particular a beam, acting as a spring. As part of the deflecting element, there is also a mass element 36 at the end of the deformable member 33, and further a deflecting protrusion 38 extending between the steady protrusions 39A, 39B.

When the device experiences acceleration in the vertical direction of FIG. 3A, the inertia of the deflecting member, in particular that of the mass element 36, causes the deformable member 33 to bend and the deflecting protrusion to be displaced. Thus, the capacitance between the deflecting protrusion 38 and steady protrusions 39A, 39B changes (capacitances over gaps 37A, 37B). If one or both of these capacitances or the differential capacitance is measured with suitable electrodes, the magnitude of acceleration can be determined.

The structure according to FIG. 3A can be arranged to the plane of a silicon wafer (to sense lateral acceleration) or out-of-plane (to sense out-of-plane acceleration). In both cases, the longitudinal axis of the deformable member can be arranged at an angle θ with respect to the [100] crystal direction.

Also structures, where the deflecting element is able to move in two orthogonal directions are possible (a 2D acceleration sensor).

In more detail, in an accelerometer of the present kind, a proof mass with mass m is suspended to a frame with a spring with a spring constant k, consisting of flexural and/or torsional spring elements. When the accelerometer experiences an acceleration a, a force F=ma is exerted between the mass and the frame. A displacement x=F/k=ma/k occurs as a result, and this is detected typically electrically. A common way of electrical detection is based on measurement of differential capacitances in a configuration like that of FIG. 3A. The measured quantity can be the normalized differential capacitance C₁(x)−C₂(x)/[C₁(x)+C₂(x)], where proportionalities C₁˜1/(d−x) and C2˜1/(d+x) hold (where d is the capacitive gap without acceleration). Assuming symmetric geometries for C₁ and C₂, the measured quantity is proportional to displacement x=F/k. Thus the temperature stability of the device is dictated by the temperature stability of the spring constant k, which was shown to be determined by the temperature coefficients of the elastic modulus and of thermal expansion, see Eq. (A). As the present tilted configuration can reduce the temperature coefficients, the overall temperature stability of the device increases.

It should be noted that FIG. 3A represents only the general principle of an acceleration sensor. In a practical accelerometer device, there are typically a plurality of protrusions that are used so as to maximize the resulting capacitance, and typically folded or meandering deformable member structures are used to create a spring with sufficiently low spring constant.

FIGS. 3B and 3C show in more detail an exemplary in-plane acceleration sensor configuration. The measurement of the acceleration can be based on the same principle as discussed above, using a deflecting protrusion 38B between steady protrusions 39BA and 39BB and capacitive measurement. However, the mass element 36B is suspended using not only one deformable member (spring) but four deformable members (springs) extending symmetrically therefrom. Each of the deformable members comprises a beam whose longitudinal axis is arranged at an angle θ with respect to the [100] crystal direction.

FIG. 3D shows still another variation of an acceleration sensor. The sensor comprises a mass element 36D again suspended at four points to a support structure 34D. The suspension is achieved by deformable elements 33D, each of which comprises a meandering structure. The deformable elements comprise first beams 33D1 and second beams 33D2 arranged at a right angle with respect to each other and connected at their ends. Both the first and second beams 33D1, 33D2 are arranged at an angle θ with respect to the [100] crystal direction. Thus, the deformable elements 33D are efficiently temperature-compensated along their whole length. Still, a very sensitive sensor is produced.

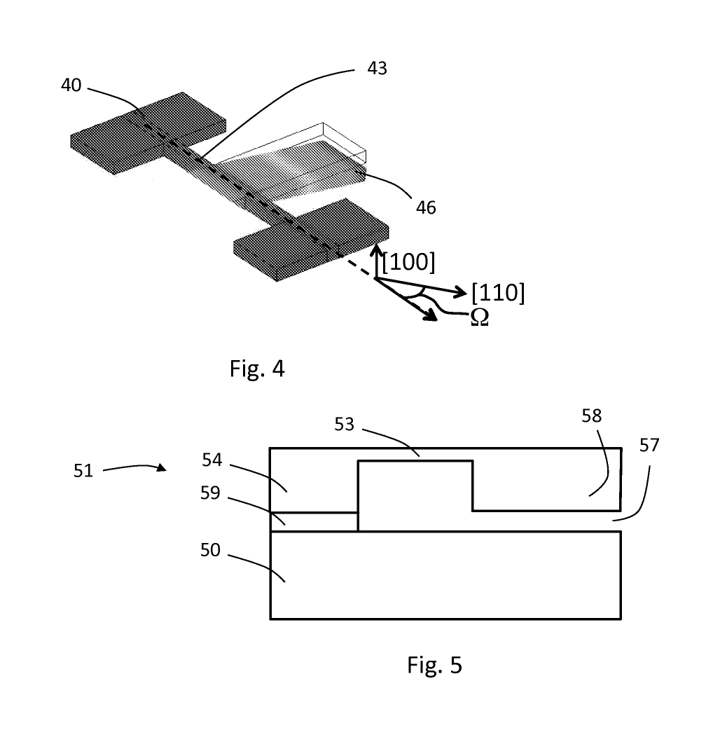

FIG. 4 shows a torsional element with two supports 40 and a beam 43 extending between the supports 40. On the beam 43, there is a mass element 46 extending perpendicularly from the beam 43. When the element experiences acceleration perpendicular to the longitudinal axis of the beam 43, the beam is torsionally deformed due to the inertia of the mass element 46. The magnitude of torsion can be measured using e.g. capacitive measurement setup (not shown) and the angular acceleration determined. By arranging the beam 43 at an angle S2 with respect to the [110] crystal direction, the torsional temperature coefficients can be minimized and the temperature stability of the device increased.

Gyroscopic Sensor

Gyroscopes are angular velocity sensors, i.e., they detect the rate of rotation. In a micromechanical gyroscope a resonant structure is excited to vibration that is typically restricted in a plane. This vibration couples to the angular velocity through the Coriolis force F_{c}, which deflects the structure to an out-of-plane direction. This deflection x can occur at a different frequency than any out-of-plane vibration mode, and is given by x=F_{c}/k, where k is the spring constant for the out-of-plane deflection in question. Thus, temperature compensated behaviour can be achieved by utilizing the present deflecting element as part of the gyroscope, whereby the spring constant k of its Coriolis force-deformable member becomes temperature compensated.

Voltage Reference

FIG. 5 shows a device structure which can be used as a voltage reference. It comprises a substrate 50, a separating layer 59 and a functional layer 51 stacked. The functional layer is shaped to comprise a steady support structure 54, a deformable member 53 and an end member 58 separated from the substrate by distance d₀ at rest, whereby a gap 57 is formed.

The deformable member 53 and end member 58 form the deflecting element. Again, the deformable member is preferably a beam arranged at an angle θ with respect to the [100] crystal direction.

The voltage reference is based on a mechanical spring formed by the deformable member 53 to which a force is exerted electrostatically (capacitively) over the gap 57. A voltage V is applied between two electrodes (not shown) on the substrate 50 and the end member 58, whereby the force tries to pull the two electrodes together. The deformable member 53 having a spring constant k provides an opposite force to balance the system. This kind of system has a so-called pull-in point, or, pull-in voltage Vₚᵢ, which can be used as an accurate voltage reference.

Micromirror

Micromechanical mirror devices are used in video projectors and optics and applications where light deflection and control is needed. By placing the mirror on a deflecting element as herein described a passively temperature compensated micromirror can be produced. Actuation of a mirror can be based on, for example, on an electrostatic force that deflects the mirror. A well-controlled deflection x, based on an adjustable force F of electric origin, can be achieved when the deflection force is counterbalanced with a spring element, described by the spring constant k: the deflection x is given by x=F/k. Temperature compensation of the spring constant k can thus temperature stabilize the deflection x, when the force F is independent of temperature. The deflection x can describe linear deflection (extension, bending) or angular deflection (torsion).

The same principle can be used also for other applications and devices that require accurate movement and temperature stability. Alternative actuation methods include magnetic and piezoelectric actuation. As explained above, the term static actuation covers non-resonant actuation, even if the movement is occurring repeatedly, such as at a controlled constant frequency or in another controlled way.

Theory and Simulations

The following considerations and simulations illustrate the feasibility and advantages of embodiments of the invention in practice. In particular, they demonstrate that zeroing of both first and second order temperature coefficients simultaneously is possible in the configurations herein discussed.

The spring constant of a flexural/extensional spring element depends on the elastic modulus (E) and the spring constant of a torsional spring element depends on the shear modulus (G) of the material the spring is made of. For isotropic materials the elastic and shear moduli E and G capture the elastic properties fully, and, the spring constant of a flexural/extensional/torsional spring is independent of the direction of the spring element.

Silicon is anisotropic, and its elastic properties are described by three independent elastic parameters c₁₁, c₁₂ and c₄₄ (instead of the two parameters E and G). It is practical, however, to define an effective elastic modulus or an effective shear modulus for a flexural/extensional/torsional spring element aligned to certain direction with respect to the silicon crystal lattice. In the following discussion the term elastic modulus E is used for denoting the effective (direction dependent) elastic modulus as well as denoting to the effective (direction dependent) shear modulus.

The elastic modulus E depends on the alignment of the spring and it is a function of the elastic parameters:

E=E(c₁₁,c₁₂,c₄₄).

For example, for an extensional spring aligned along the [100] crystalline direction, the elastic modulus would be approximately given by

E=c₁₁−2*c₁₂²/(c₁₁+c₁₂).

Numerical finite element analysis can be used to accurately calculate the value of the elastic modulus and its dependence (or sensitivity) on the parameters c₁₁, c₁₂ and c₄₄.

Because the elastic constants c₁₁, c₁₂ and c₄₄ are temperature dependent, also E is temperature dependent. The temperature dependent elastic modulus can be expanded as power series as

E(T)=E₀×[1+TCE₁×(T−T₀)+TCE₂×(T−T₀)²],

where the constants TCE₁ and TCE₂ are the first- and second-order temperature coefficients of the elastic modulus, and T₀ is the reference temperature (typically 25° C.). The relative change of E, i.e., ΔE/E₀, is given as

ΔE/E₀=(E(T)−E₀)/E₀=TCE₁×(T−T₀)+TCE₂×(T−T₀)².

Thermal expansion can be expressed with a power series in the same manner as was used for elastic modulus E above:

L(T)=L₀×[1+TCL₁×(T−T₀)+TCL₂×(T−T₀)²],

where TCL₁ and TCL₂, are the first and second order temperature coefficients of expansion, respectively.

In the discussion below, thermal expansion of silicon and of silicon dioxide (SiO₂) are of interest. For silicon, literature values and notations TCL_{Si,1}=+2.6 ppm/C and TCL_{Si,2}=+8.5 ppb/C and for silicon dioxide TCL_{SiO2,1}=0.6 ppm/C and TCL_{SiO2,2}=0 ppb/C are used, respectively.

As will be shown below the effect of thermal expansion is relatively small with respect to that of elastic modulus E, and can be often neglected for practical purposes.

The temperature coefficients discussed in this document are denoted as TCx or TC(x), where “x” is the quantity of interest. Examples are TCE and TCk, where E and k are the elastic modulus and spring constant, respectively. When a subscript is omitted from TCx, it is assumed that the first order temperature coefficient TCx₁ is discussed.

In FIG. 6A, the parameters zeroing temperature coefficients TCE₁ and TCE₂ of an extensional/flexural spring element are shown and the optimal point (theta, doping level) highlighted at which both TCE₁ and TCE₂ are simultaneously zero.

FIG. 6B is similar to FIG. 6A, but instead of investigating the temperature coefficients of the elastic modulus E alone, also thermal expansion of silicon is taken into account by summing the terms TCE₁+TCL_{si,1} or TCE₂+TCL_{si,2} (denoted as TC(E+Lₛᵢ)₁ or TC(E+Lₛᵢ)₂ in the figure), see Eq. A. This is a relevant case for all embodiments where a spring is utilized. It can be seen that a spring can be fully temperature stabilized with correct doping level and with correct orientation of the spring elements.

FIG. 6C illustrates the thermal stability parameters of a voltage reference device according to FIG. 5, i.e. parameters stabilizing the pull-in voltage Vₚᵢ. The operation principle of a voltage reference device is illustrated e.g., in Karkkainen, A., N. et al, “MEMS-Based AC Voltage Reference.” IEEE Transactions on Instrumentation and Measurement 54, no. 2 (April 2005): 595-99. doi:10.1109/TIM.2004.843422. The pull-in voltage Vₚᵢ is given by

Vₚᵢ=sqrt(8/27)*d₀*sqrt(k/C₀), (Eq. B)

where d₀ is the gap between the electrodes, k is the spring constant and C₀=ε*A/d₀ is the capacitance between the electrodes (ε is the permittivity and A is the (effective) area of the electrode).

The temperature coefficient of Vₚᵢ in Eq. B can be derived to be

TC(Vₚᵢ)=[TCE+3×TCL_{SiO2}−TCLₛᵢ]/2

i.e. a combination of the temperature coefficients of the elastic modulus and the thermal expansion of the materials of the stack forming the device. In this example, with reference to FIG. 5, it is assumed that the separating layer 59 is formed of silicon dioxide while other materials are silicon.

In FIG. 6C, 2×TC(Vₚᵢ)=TCE+3×TCL_{siO2}-TCLₛᵢ is plotted. Comparison to FIG. 6A shows that the contribution from the thermal expansion terms is relatively small and affecting only slightly to the optimal configuration (θ, n) where both first and second order temperature coefficients are zeroed.

It is to be understood that the embodiments of the invention disclosed are not limited to the particular structures, process steps, or materials disclosed herein, but can be extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In this description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

1. A micromechanical device comprising
a support structure,
a deflecting element connected to the support structure, wherein the deflecting element comprises at least one deformable member adapted to deform extensionally, flexurally or torsionally with respect to a deformation axis for allowing deflection of the deflecting element with respect to the support structure,
means for statically deflecting the deflecting element or detecting the magnitude of static deflection of the deflecting element,
wherein
the deformable member is manufactured from silicon doped with an n-type doping agent to a doping concentration of at least 1.1*10²⁰ cm⁻³.

2. The device according to claim 1, wherein said extensional, flexural or torsional deformation of the deformable member is affected by anisotropic elastic properties of silicon when the deflecting element is deflected with respect to the support structure.

3. The device according to claim 2, wherein shape and orientation of the deformable member with respect to its crystal structure are chosen, in combination with the selected doping concentration, so that the deformation is affected by said anisotropic properties in a way simultaneously zeroing the first and second order temperature coefficients of elasticity of the deformable member.

4. The device according to claim 1, wherein the deflecting element is manufactured from an or oriented silicon wafer.

5. The device according to claim 4, wherein
said deformation is adapted to be extensional or flexural, and
the deformation axis of the deformable member is oriented at an angle of 20±20 degrees with respect to the crystal direction of the wafer.

6. The device according to claim 4, wherein
said deformation is adapted to be extensional or flexural, and
the deformation axis of the deformable member is oriented at an angle of 20±15 or 17±10 degrees with respect to the crystal direction of the wafer.

7. The device according to claim 4, wherein
said deformation is adapted to be torsional, and
the deformation axis of the deformable member is oriented at an angle of 0±35 degrees, such as ±5 . . . 30 degrees with respect to the crystal direction of the wafer.

8. The device according to claim 1, wherein the deformable member comprises a beam whose deformation axis is oriented along the longitudinal axis or a transverse axis of the beam.

9. The device according to claim 1, wherein the deformable member comprises a plate manufactured from a oriented silicon wafer spanned to the support structure as a flexurally deformable membrane, and wherein the dimensions of the plate and angle with respect to the crystal direction of the wafer are chosen to provide a lower first order temperature coefficient of elasticity for the plate than that of a square plate with main axes parallel to the crystal direction of the wafer.

10. The device according to claim 9, wherein the plate has an aspect ratio different from 1:1.

11. The device according to claim 1, wherein the doping concentration, shape and orientation of the deformable member are chosen so as to provide the first order temperature coefficient of elasticity of the deflecting member below 1 ppm/C.

12. The device according to claim 1, wherein the doping concentration, shape and orientation of the deformable member are chosen so as to provide the second order temperature coefficient of elasticity of the deflecting member below 24 ppb/C².

13. The device according to claim 1, wherein said deflecting element comprises, in addition to the at least one deformable member, at least one a non-deformable member, which is adapted to move due to the deformation of the at least one deformable member.

14. The device according to claim 1, wherein the device is a sensor device where the deformable member is arranged as a flexural, extensional or torsional spring and the device comprising means for detecting the magnitude of static deflection of the deflecting element.

15. The device according to claim 1, wherein the device is a pressure sensor or acoustic sensor, wherein the deflecting element forms a diaphragm adapted to deflect through flexural deformation of the at least one deformable member forming at least part of the diaphragm due to external pressure affecting the deflecting element.

16. The device according to claim 15, wherein the diaphragm comprises
a non-deformable central portion and wherein the at least one deformable member is located between the central member and the support structure in ring formation, such as in the form of a plurality of interconnected beams, having a thickness smaller than the central member, or
a flexural membrane forming the deformable member, the membrane having an in-plane aspect ratio which is different from 1:1, or which is 2:1 or more, or which is 3:1 or more, or
a mesh of beams forming said deformable members, and wherein at least some of the beams are arranged at a non-zero angle with respect to the crystal direction of silicon.

17. The device according to claim 1, wherein the device is an accelerometer, wherein the deflecting element comprises a mass element suspended to the supporting structure by said at least one deformable member, whereby the at least one deformable member is adapted to deform, preferably flexurally or torsionally, due to acceleration experienced by the device.

18. The device according to claim 1, wherein the device is a gyroscopic sensor, wherein the deformable member is arranged as a Coriolis force-deformable member thereof.

19. The device according to claim 1, wherein the device is a micromechanical drive comprising means for exerting a static force on the deflecting element for deforming the deformable member.

20. The device according to claim 1, wherein the device is a voltage reference device comprising means for exerting an electrostatic force on the deflecting element for deforming the deformable member by means of a voltage.

21. (canceled)
